(19) United States
(12) Patent Application Publication
(10) Pub. No.: US 2026/0190550 A1
(43) Pub. Date: Jul. 2, 2026

(54) ASSEMBLY SUBSTRATE

(71) Applicant: LG Display Co., Ltd., Seoul (KR)

(72) Inventors: Kiyong YANG, Seoul (KR); KyuOh KWON, Paju-si (KR); SeungJun LEE, Paju-si (KR); Myungsoo HAN, Goyang-si (KR)

(73) Assignee: LG Display Co., Ltd., Seoul (KR)

(21) Appl. No.: 19/360,564

(22) Filed: Oct. 16, 2025

(30) Foreign Application Priority Data
Dec. 31, 2024 (KR) 10-2024-0202598

(51) Int. Cl. H10H 20/831; H10H 20/01; H10H 20/821; H10H 20/85; H10H 20/857

(52) U.S. Cl. CPC H10H 20/831; H10H 20/032; H10H 20/0364; H10H 20/821; H10H 20/8508; H10H 20/857

(57) ABSTRACT

An assembly substrate includes a plurality of first assembly electrodes disposed on an assembly base substrate, a plurality of second assembly electrodes disposed on the assembly base substrate so as to face the plurality of first assembly electrodes, a plurality of third assembly electrodes disposed on the assembly base substrate, a plurality of fourth assembly electrodes disposed on the assembly base substrate so as to face the plurality of third assembly electrodes, and a first organic layer including a plurality of first openings overlapping the plurality of first assembly electrodes and the plurality of second assembly electrodes, and a plurality of second openings overlapping the plurality of third assembly electrodes and the plurality of fourth assembly electrodes, the plurality of second openings having a smaller size than the plurality of first openings. Accordingly, by filtering defective light emitting diodes, an assembly rate of normal light emitting diodes may be improved.

### CROSS-REFERENCE TO RELATED APPLICATIONS

This application claims the priority of Korean Patent Application No. 10-2024-0202598filed on Dec. 31, 2024, in the Korean Intellectual Property Office, the disclosure of which is incorporated herein by reference.

### BACKGROUND

### Technical Field

The present disclosure relates to an assembly substrate that may improve the assembly rate of normal light emitting diodes by filtering defective light emitting diodes.

### Description of the Related Art

Display devices used in computer monitors, TVs, and mobile phones include organic light emitting display (OLED) devices that emit light by themselves, and liquid crystal display (LCD) devices that require a separate light source.

The application range of display devices is expanding from computer monitors and TVs to personal portable devices, and research is being conducted on display devices having a large display area while having reduced volume and weight.

In addition, recently, display devices including light emitting diodes (LEDs) have attracted attention as next-generation display devices. Since LEDs are made of inorganic materials rather than organic materials, they have excellent reliability and longer lifespans compared to liquid crystal display devices and organic light emitting display devices. Moreover, LEDs not only have a fast lighting speed but also exhibit excellent light emission efficiency, strong impact resistance for high stability, and the capability to display high-brightness images.

### BRIEF SUMMARY

An object to be achieved by the present disclosure is to provide an assembly substrate capable of filtering defective light emitting diodes.

Another object to be achieved by the present disclosure is to provide an assembly substrate in which the assembly rate of normal light emitting diodes is improved by filtering defective light emitting diodes.

Still another object to be achieved by the present disclosure is to provide an assembly substrate capable of easily assembling a plurality of light emitting diodes to improve production efficiency.

Objects of the present disclosure are not limited to the above-mentioned objects, and other objects, which are not mentioned above, can be clearly understood by those skilled in the art from the following descriptions.

According to an aspect of the present disclosure, there is provided an assembly substrate for assembling a plurality of light emitting diodes. The assembly substrate includes an assembly base substrate, a plurality of first assembly electrodes disposed on the assembly base substrate, a plurality of second assembly electrodes disposed on the assembly base substrate so as to face the plurality of first assembly electrodes, a plurality of third assembly electrodes disposed on the assembly base substrate, a plurality of fourth assembly electrodes disposed on the assembly base substrate so as to face the plurality of third assembly electrodes, and a first organic layer including a plurality of first openings overlapping the plurality of first assembly electrodes and the plurality of second assembly electrodes, and a plurality of second openings overlapping the plurality of third assembly electrodes and the plurality of fourth assembly electrodes, the plurality of second openings having a smaller size than the plurality of first openings. Accordingly, by filtering defective light emitting diodes, an assembly rate of normal light emitting diodes may be improved.

Other detailed matters of the exemplary embodiments are included in the detailed description and the drawings.

According to the present disclosure, a separate opening for defective light emitting diodes may be included to filter the defective light emitting diodes.

According to the present disclosure, an opening for defective light emitting diodes may be formed different from an opening for normal light emitting diodes so that the defective light emitting diodes are not transferred onto the display panel.

According to the present disclosure, by filtering defective light emitting diodes, the assembly rate and transfer rate of normal light emitting diodes may be improved.

The present disclosure may implement process optimization by assembling a plurality of light emitting diodes on a large-area assembly substrate.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an enlarged plan view of an assembly area of an assembly substrate according to an exemplary embodiment of the present disclosure;

FIG. 2 is a cross-sectional view taken along A-A′ of FIG. 1;

FIGS. 3A to 3D are process diagrams illustrating a method of manufacturing a display device using an assembly substrate according to an exemplary embodiment of the present disclosure;

FIG. 4 is an enlarged plan view of an assembly area of an assembly substrate according to another exemplary embodiment of the present disclosure;

FIG. 5 is a cross-sectional view taken along B-B′ of FIG. 4;

FIG. 6 is an enlarged plan view of an assembly area of an assembly substrate according to still another exemplary embodiment of the present disclosure;

FIG. 7 is an enlarged plan view of an assembly area of an assembly substrate according to still another exemplary embodiment of the present disclosure; and

FIG. 8 is an enlarged plan view of an assembly area of an assembly substrate according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an assembly substrate according to exemplary embodiments of the present disclosure will be described in detail with reference to accompanying drawings

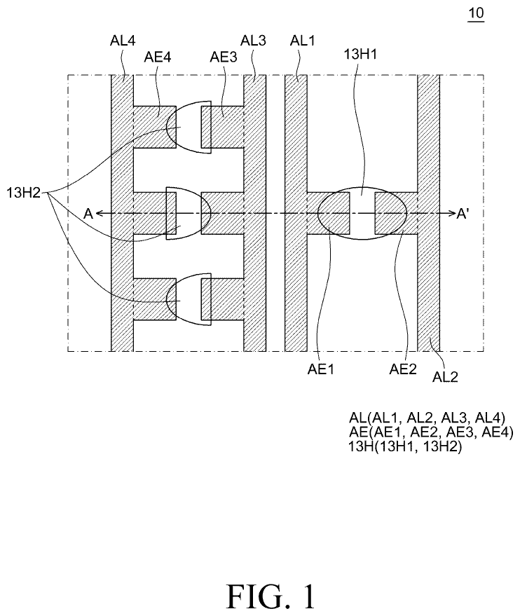

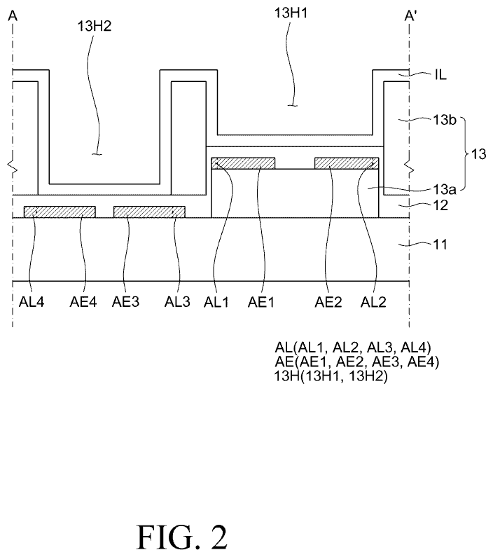

FIG. 1 is an enlarged plan view of an assembly area of an assembly substrate according to an exemplary embodiment of the present disclosure. FIG. 2 is a cross-sectional view taken along A-A′ of FIG. 1. In FIG. 1, a part of the assembly area of the assembly substrate according to an exemplary embodiment of the present disclosure is illustrated, and the assembly substrate 10 may be configured with a structure in which the area illustrated in FIG. 1 is repeated.

Referring to FIGS. 1 and 2 together, the assembly substrate 10 may include an assembly base substrate 11, a plurality of assembly lines AL, a plurality of assembly electrodes AE, a passivation layer 12, an organic layer 13, and a protective layer IL.

First, the plurality of assembly lines AL and the plurality of assembly electrodes AE may be disposed on the assembly base substrate 11.

The plurality of assembly lines AL includes a first assembly line AL1, a second assembly line AL2, a third assembly line AL3, and a fourth assembly line AL4.

First, the first assembly line AL1 and the second assembly line AL2 may be disposed to be spaced apart from each other at a predetermined interval. Different voltages are applied to the first assembly line AL1 and the second assembly line AL2 so that an electric field may be formed between the first assembly line AL1 and the second assembly line AL2. The plurality of light emitting diodes may be self-assembled between the first assembly line AL1 and the second assembly line AL2 using the electric field formed between the first assembly line AL1 and the second assembly line AL2. For example, the first assembly line AL1 and the second assembly line AL2 may be assembly lines for assembling normal light emitting diodes.

The third assembly line AL3 and the fourth assembly line AL4 may be disposed to be spaced apart from each other at a predetermined interval. Different voltages are applied to the third assembly line AL3 and the fourth assembly line AL4 so that an electric field may be formed between the third assembly line AL3 and the fourth assembly line AL4. The plurality of light emitting diodes may be self-assembled between the third assembly line AL3 and the fourth assembly line AL4 using the electric field formed therebetween. For example, the third assembly line AL3 and the fourth assembly line AL4 may be assembly lines for assembling defective light emitting diodes, for example, only defective light emitting diodes in which a part of normal light emitting diodes is damaged.

Meanwhile, the third assembly line AL3 may be configured such that the same voltage as that applied to the first assembly line AL1 is applied thereto, and the fourth assembly line AL4 may be configured such that the same voltage as that applied to the second assembly line AL2 is applied thereto, but is not limited thereto.

The plurality of assembly electrodes AE may include a plurality of first assembly electrodes AE1, a plurality of second assembly electrodes AE2, a plurality of third assembly electrodes AE3, and a plurality of fourth assembly electrodes AE4.

The plurality of first assembly electrodes AE1 may be connected to the first assembly line AL1, the plurality of second assembly electrodes AE2 may be connected to the second assembly line AL2, the plurality of third assembly electrodes AE3 may be connected to the third assembly line AL3, and the plurality of fourth assembly electrodes AE4 may be connected to the fourth assembly line AL4. A pair of the first assembly electrode AE1 and the second assembly electrode AE2 may be disposed adjacent to each other to form an electric field for self-assembling a light emitting diode. Each of the pair of the first assembly electrode AE1 and the second assembly electrode AE2 may be disposed to correspond to an exact position where a light emitting diode is transferred in a plurality of sub pixels. In addition, a pair of the third assembly electrode AE3 and the fourth assembly electrode AE4 may be disposed adjacent to each other to form an electric field for self-assembling a light emitting diode. The third assembly electrode AE3 and the fourth assembly electrode AE4 may be assembly electrodes for assembling defective light emitting diodes. Accordingly, each of the pair of the third assembly electrode AE3 and the fourth assembly electrode AE4 may be disposed irrespective of the exact position where a light emitting diode is transferred in a plurality of sub pixels, but is not limited thereto.

The plurality of assembly lines AL and the plurality of assembly electrodes AE may be made of a conductive material, for example, copper (Cu), chromium (Cr), molybdenum (Mo), molybdenum titanium (MoTi), or the like, but is not limited thereto. In addition, the plurality of assembly lines AL and the plurality of assembly electrodes AE may be formed of a plurality of conductive layers. For example, the plurality of assembly lines AL and the plurality of assembly electrodes AE may be formed in a multi-layered structure including a conductive layer having relatively excellent conductivity and a clad layer having relatively high corrosion resistance disposed to cover the conductive layer, but is not limited thereto.

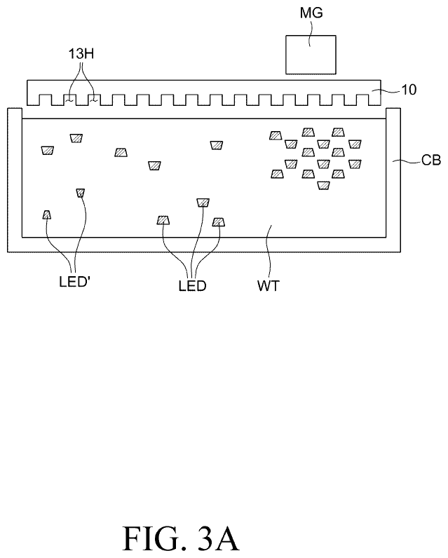

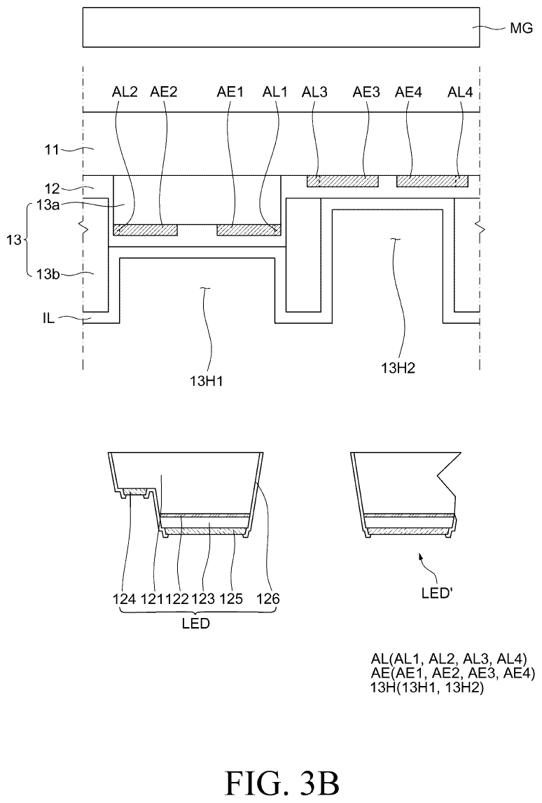

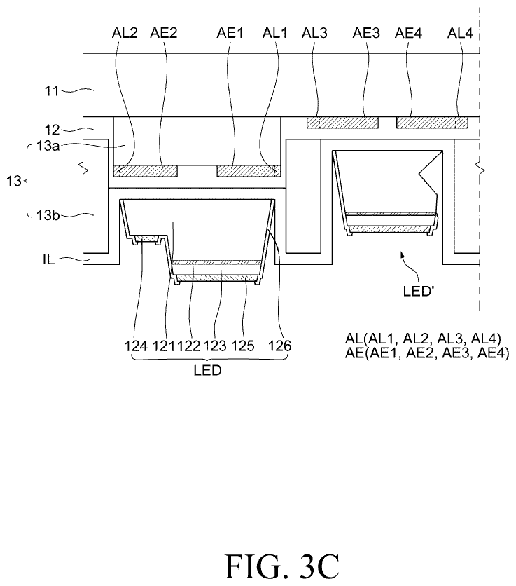

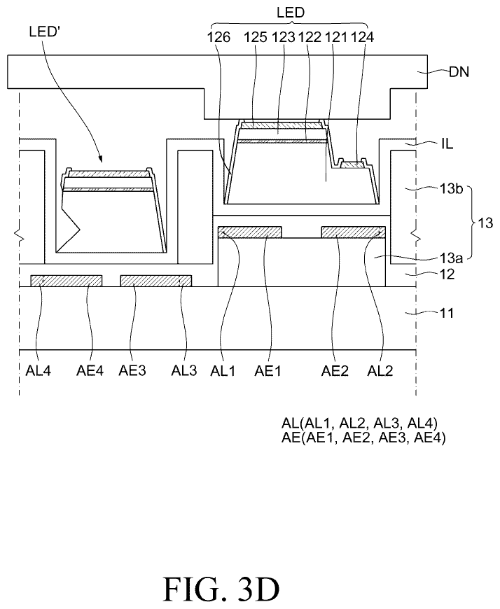

A second organic layer 13a may be disposed between the first assembly electrode AE1, the first assembly line AL1, the second assembly electrode AE2, and the second assembly line AL2 and the assembly base substrate 11. In other words, the second organic layer 13a may be disposed to overlap only with a first opening 13H1 among the first opening 13H1 and a second opening 13H2. Accordingly, the depth of an opening of a first organic layer 13b disposed on the second organic layer 13a may be formed to be different. That is, the depth of the first opening 13H1 overlapping with the second organic layer 13a may be shallower than the depth of the second opening 13H2 not overlapping with the second organic layer 13a. Details regarding this will be described in detail with reference to FIGS. 3A to 3D to be described later.

Meanwhile, since the first assembly electrode AE1 and the second assembly electrode AE2 are disposed on the second organic layer 13a, the height of the first assembly electrode AE1 and the second assembly electrode AE2 may be higher than the height of the third assembly electrode AE3 and the fourth assembly electrode AE4 disposed on the assembly base substrate 11. Likewise, the height of the first assembly line AL1 and the second assembly line AL2 may be higher than the height of the third assembly line AL3 and the fourth assembly line AL4.

The second organic layer 13a may be formed of a single layer or multiple layers of an organic insulating material and may be made of, for example, benzocyclobutene or acryl-based organic material, but is not limited thereto.

A passivation layer 12 may be disposed on the plurality of assembly lines AL, the plurality of assembly electrodes AE, and the second organic layer 13a. The passivation layer 12 may protect the plurality of assembly lines AL and the plurality of assembly electrodes AE from fluid, thereby suppressing defects such as corrosion of the plurality of assembly lines AL and the plurality of assembly electrodes AE.

The passivation layer 12 may be formed of, for example, an oxide or a nitride, and may be formed of a single layer or multiple layers of silicon oxide (SiOₓ) or silicon nitride (SiNₓ), but is not limited thereto.

Next, a first organic layer 13b including a plurality of openings 13H may be disposed on the passivation layer 12.

The plurality of openings 13H may include a plurality of first openings 13H1 and a plurality of second openings 13H2. The first opening 13H1 may be disposed to overlap an area between a pair of the first assembly electrode AE1 and the second assembly electrode AE2. The second opening 13H2 may be disposed to overlap an area between a pair of the third assembly electrode AE3 and the fourth assembly electrode AE4.

The first opening 13H1 and the second opening 13H2 may include a first opening 13H1 and a second opening 13H2 having different sizes and shapes from each other.

The size of the plurality of second openings 13H2 may be smaller than the size of the plurality of first openings 13H1. For example, the plurality of second openings 13H2 may have a shape relatively narrower and deeper than the plurality of first openings 13H1. Accordingly, the planar area of the second opening 13H2 may be smaller than the planar area of the first opening 13H1.

Specifically, the planar shape of the plurality of first openings 13H1 may have a shape corresponding to the planar shape of the light emitting diode. In addition, the width of the first opening 13H1 may be greater than the maximum width of the light emitting diode. Accordingly, the light emitting diode may be seated in the first opening 13H1. Further, since the plurality of first openings 13H1 is formed by removing the first organic layer 13b disposed on the second organic layer 13a, the depth thereof may be relatively shallow. Accordingly, the light emitting diode assembled in the first opening 13H1 may be disposed relatively closer to a donor when being transferred to the donor. Thus, the light emitting diode assembled in the first opening 13H1 may easily contact the donor and be transferred onto the donor.

The width of the plurality of second openings 13H2 may be smaller than the maximum width of the light emitting diode. For example, the planar shape of the second opening 13H2 may be formed in a shape corresponding to a part of the light emitting diode. Accordingly, a normal light emitting diode may not be assembled in the second opening 13H2, and only a defective light emitting diode, for example, in which a part of the normal light emitting diode is damaged, may be assembled in the second opening 13H2. In other words, the planar shape of the second opening 13H2 may be formed as a part of the planar shape of the first opening 13H1. Therefore, the planar area of the second opening 13H2 may be smaller than the planar area of the first opening 13H1.

In addition, since the plurality of second openings 13H2 has a relatively deeper depth, the defective light emitting diode assembled in the second opening 13H2 may be disposed relatively farther from the donor. Accordingly, the defective light emitting diode assembled in the second opening 13H2 may not contact the donor. Therefore, a defect in which the defective light emitting diode is transferred onto the donor may be minimized.

A protective layer IL may be disposed on the first organic layer 13b. For example, the protective layer IL may cover the side surface of the first organic layer 13b and the top surface of the first organic layer 13b. In addition, the protective layer IL may cover the top surface of the passivation layer 12 exposed in the opening 13H to protect the plurality of assembly lines AL, the plurality of assembly electrodes AE, and the organic layer 13 from fluid, thereby suppressing defects such as corrosion of the plurality of assembly lines AL.

The first organic layer 13b may be formed of a single layer or multiple layers of an organic insulating material, and may be made of, for example, benzocyclobutene or acryl-based organic material, but is not limited thereto.

Hereinafter, a method of manufacturing a display device using the assembly substrate 10 according to an exemplary embodiment of the present disclosure will be described with reference to FIGS. 3A to 3D.

FIGS. 3A to 3D are process diagrams illustrating a method of manufacturing a display device using an assembly substrate according to an exemplary embodiment of the present disclosure. FIGS. 3A to 3C are diagrams illustrating a process of self-assembling a light emitting diode LED on the assembly substrate 10. FIG. 3D is a diagram illustrating a process of transferring the light emitting diode LED on the assembly substrate 10 to a donor DN.

Referring to FIG. 3A, the plurality of light emitting diodes LED is self-assembled on the assembly substrate 10.

First, the plurality of light emitting diodes LED grown on a wafer is introduced into a chamber CB filled with a fluid WT. The fluid WT may include water, and the chamber CB filled with the fluid WT may have an open-top shape.

At this time, the light emitting diode LED may include a magnetic material so as to be moved by a magnetic field. For example, the light emitting diode LED may include a first semiconductor layer 121, an emission layer 122, a second semiconductor layer 123, a first electrode 124, a second electrode 125, and an encapsulation film 126, and any one of the first electrode 124 and the second electrode 125 of the light emitting diode LED may include a ferromagnetic material. For example, the second electrode 125 may include a ferromagnetic material such as nickel (Ni) and cobalt (Co).

Specifically, referring also to FIG. 3B, the second semiconductor layer 123 is disposed on the first semiconductor layer 121. The first semiconductor layer 121 and the second semiconductor layer 123 may be layers formed by doping n-type and p-type impurities into specific materials. For example, each of the first semiconductor layer 121 and the second semiconductor layer 123 may be a layer in which n-type and p-type impurities are doped into a material such as aluminum gallium indium phosphide (AlGaInP), indium aluminum phosphide (InAlP), gallium arsenide (GaAs), or gallium nitride (GaN). The p-type impurity may be magnesium, zinc (Zn), or beryllium (Be), and the n-type impurity may be silicon (Si), germanium, or tin (Sn), but is not limited thereto.

A portion of the first semiconductor layer 121 may protrude to be disposed outside the second semiconductor layer 123. The top surface of the first semiconductor layer 121 may be configured as a lateral-type light emitting diode LED having a portion overlapping the bottom surface of the second semiconductor layer 123 and a portion disposed outside the bottom surface of the second semiconductor layer 123. However, the size and shape of the first semiconductor layer 121 and the second semiconductor layer 123 may be variously modified, but is not limited thereto.

The first electrode 124 is disposed on the first semiconductor layer 121. The first electrode 124 may be disposed on the top surface of the first semiconductor layer 121 exposed from the emission layer 122 and the second semiconductor layer 123. The first electrode 124 may be formed of a conductive material such as a transparent conductive material like indium tin oxide (ITO) or indium zinc oxide (IZO), or an opaque conductive material like titanium (Ti), gold (Au), silver (Ag), copper (Cu), or an alloy thereof, but is not limited thereto.

The second electrode 125 is disposed on the second semiconductor layer 123. The second electrode 125 may be disposed on the top surface of the second semiconductor layer 123. The second electrode 125 may be formed of a conductive material such as a transparent conductive material like indium tin oxide (ITO) or indium zinc oxide (IZO), or an opaque conductive material like titanium (Ti), gold (Au), silver (Ag), copper (Cu), or an alloy thereof, but is not limited thereto.

In this case, any one of the first electrode 124 and the second electrode 125 may include a ferromagnetic material. For example, the second electrode 125 may include a ferromagnetic material such as nickel (Ni) and cobalt (Co).

Next, an encapsulation film 126 enclosing the first semiconductor layer 121, the emission layer 122, the second semiconductor layer 123, the first electrode 124, and the second electrode 125 is disposed. The encapsulation film 126 may be made of an insulating material to protect the first semiconductor layer 121, the emission layer 122, and the second semiconductor layer 123. A contact hole exposing the first electrode 124 and the second electrode 125 may be formed in the encapsulation film 126 so that they may be electrically connected to the display panel.

Then, the assembly substrate 10 may be positioned above the chamber CB filled with the light emitting diodes LED. The assembly substrate 10 having a plurality of openings 13H may be disposed to face the chamber CB.

Then, a magnet MG may be positioned on the assembly substrate 10. The light emitting diodes LED sunk to the bottom of the chamber CB or floating in the chamber CB may move toward the assembly substrate 10 by the magnetic force of the magnet MG.

Next, referring to FIG. 3C, the light emitting diodes LED moved toward the assembly substrate 10 by the magnet MG may be self-assembled on the assembly substrate 10 by an electric field formed between the plurality of assembly electrodes AE.

A voltage is applied to the plurality of assembly lines AL and the plurality of assembly electrodes AE to self-assemble the plurality of light emitting diodes into each of the plurality of openings 13H. By this electric field, the light emitting diode LED may be dielectrically polarized to have polarity. The dielectrically polarized light emitting diode LED may move or be fixed in a specific direction by dielectrophoresis (DEP), that is, by the electric field. Therefore, the plurality of light emitting diodes LED may be self-assembled inside each of the plurality of openings 13H using the dielectrophoresis.

Specifically, a defective light emitting diode may first be assembled inside the second opening 13H2. For example, different alternating voltages may be applied to the third assembly line AL3 and the plurality of third assembly electrodes AE3 overlapping the second opening 13H2 and to the fourth assembly line AL4 and the plurality of fourth assembly electrodes AE4 to form an electric field. By this electric field, the defective light emitting diode LED′ may be self-assembled inside the second opening 13H2.

On the other hand, since the width of the second opening 13H2 is smaller than the maximum width of the normal light emitting diode LED, the normal light emitting diode LED may not be assembled inside the second opening 13H2 and may float in the chamber CB.

Then, different alternating voltages may be applied to the first assembly line AL1 and the first assembly electrode AE1 overlapping the first opening 13H1 and to the second assembly line AL2 and the second assembly electrode AE2 to form an electric field. By this electric field, the light emitting diode LED floating in the chamber CB may be self-assembled inside the first opening 13H1.

After the self-assembly is completed, the fluid WT may be evaporated from the assembly substrate 10. At this time, until the fluid WT is completely evaporated, an electric field may be formed between the assembly electrodes AE to fix the light emitting diode LED inside the first opening 13H1 and the defective light emitting diode LED′ inside the second opening 13H2. When drying of the assembly substrate 10 is completed, the electric field may be removed. At this time, even after the electric field is removed, the light emitting diode LED may be temporarily fixed to the assembly substrate 10 through van der Waals force.

Next, referring to FIG. 3D, the plurality of light emitting diodes LED on the assembly substrate 10 is transferred to a donor DN.

First, the assembly substrate 10 and the donor DN are aligned such that the plurality of light emitting diodes LED faces the donor DN. After aligning the assembly substrate 10 and the donor DN, the assembly substrate 10 and the donor DN are attached to each other so that the upper portions of the light emitting diodes LED may contact the donor DN. At this time, since the donor DN is made of a material having adhesiveness, the plurality of light emitting diodes LED may be adhered at their upper portions to the donor DN and moved from the assembly substrate 10 to the donor DN.

The donor DN may be made of a polymer material having viscoelasticity, for example, poly dimethyl siloxane (PDMS), poly urethane acrylate (PUA), poly ethylene glycol (PEG), poly methyl meth acrylate (PMMA), poly styrene (PS), epoxy resin, urethane resin, acryl resin, but is not limited thereto.

Meanwhile, the donor DN may include a protrusion. The protrusion of the donor DN may be disposed to correspond to the first opening 13H1. Accordingly, the protrusion of the donor DN may contact the normal light emitting diode LED. As described above, since the second organic layer 13a is disposed in the area overlapping the first opening 13H1, the depth of the first opening 13H1 may be lower than the height of the normal light emitting diode LED and may be relatively shallower than the depth of the second opening 13H2. That is, the normal light emitting diode LED assembled in the first opening 13H1 may protrude outside the first opening 13H1 and be positioned relatively higher than the defective light emitting diode LED′ assembled in the second opening 13H2. Accordingly, the normal light emitting diode LED may more easily contact the donor DN.

On the other hand, the second organic layer 13a may not be disposed in the area overlapping the second opening 13H2. Accordingly, the depth of the second opening 13H2 may be deeper or greater than the height of the defective light emitting diode LED′ and may be relatively deeper than the depth of the first opening 13H1. That is, the defective light emitting diode LED′ assembled in the second opening 13H2 is positioned relatively lower than the normal light emitting diode LED assembled in the first opening 13H1, and since the depth of the second opening 13H2 is greater than the height of the defective light emitting diode LED′, the defective light emitting diode LED′ assembled in the second opening 13H2 may not protrude outside the second opening 13H2. Accordingly, the defective light emitting diode LED′ assembled in the second opening 13H2 may not contact the donor DN. Therefore, a defect in which the defective light emitting diode is transferred onto the donor DN may be minimized.

Although not illustrated in the drawings, the plurality of light emitting diodes LED on the donor DN may be transferred onto the display panel.

In addition, by removing an electric field formed between the third assembly electrode AE3 and the fourth assembly electrode AE4 overlapping the second openings 13H2 in the assembly substrate 10, defective light emitting diodes LED′ assembled in the second openings 13H2 may be removed from the assembly substrate 10.

One method of manufacturing a display device may use a self-assembly method. The display device may be manufactured by self-assembling the light emitting diodes on a separate assembly substrate and then transferring the self-assembled light emitting diodes from the assembly substrate to a substrate for the display panel using a donor.

Specifically, after dispersing the light emitting diodes in a chamber containing a fluid, an assembly substrate including grooves for assembling the light emitting diodes may be disposed above the chamber. At this time, a magnet may be positioned on the assembly substrate so that the light emitting diodes sunk to the bottom of the chamber or floating in the chamber may be moved toward the assembly substrate by the magnetic force of the magnet.

However, as the size of the light emitting diode is miniaturized to the micron level, defects in which the light emitting diode is easily broken during an assembly process may also occur. For example, in the case of a lateral-type light emitting diode, a portion of the first semiconductor layer may be disposed to protrude beyond the outer side of the second semiconductor layer. In this case, defects in which the protruding portion of the first semiconductor layer is easily broken during the assembly process may mainly occur. When a defective light emitting diode is assembled in this manner, there is a problem in that the normal light emitting diode cannot be assembled as much as the defective light emitting diode is assembled. This decrease in the assembly rate of the normal light emitting diode may lead to a decrease in the transfer rate of the light emitting diode.

Accordingly, the assembly substrate 10 according to an exemplary embodiment of the present disclosure may include the first opening 13H1 and the second opening 13H2 having different sizes. For example, the maximum width of the first opening 13H1 may be formed greater than the maximum width of the light emitting diode LED so as to accommodate the light emitting diode LED. On the other hand, the maximum width of the second opening 13H2 may be formed smaller than the maximum width of the light emitting diode LED. Therefore, the second opening 13H2 may not allow a normal light emitting diode LED to be assembled, but only a defective light emitting diode LED′ in which a part of the normal light emitting diode LED is broken may be assembled. Accordingly, an electric field may first be formed in the assembly electrodes AE and the assembly lines AL overlapping the second opening 13H2 to assemble the defective light emitting diode LED′ in the second opening 13H2. That is, the second opening 13H2 may serve to filter the defective light emitting diode LED′. In this way, when the defective light emitting diode LED′ is first assembled in the second opening 13H2, the amount of the remaining defective light emitting diodes LED′ may be reduced, thereby improving the assembly rate of the normal light emitting diode LED in the first opening 13H1.

In particular, in the assembly substrate 10 according to an exemplary embodiment of the present disclosure, the second opening 13H2 in which the defective light emitting diode LED′ is assembled is formed deeper than the first opening 13H1, and the depth of the second opening 13H2 is greater than the height of the defective light emitting diode LED′, so that even when the light emitting diode LED is transferred to the donor DN, the defective light emitting diode LED′ may not contact the donor DN. Accordingly, a defect in which the defective light emitting diode LED′ is transferred onto a display panel through the donor DN may be minimized. That is, in the assembly substrate 10 according to an exemplary embodiment of the present disclosure, the transfer rate of the normal light emitting diode LED may be improved, thereby improving production efficiency.

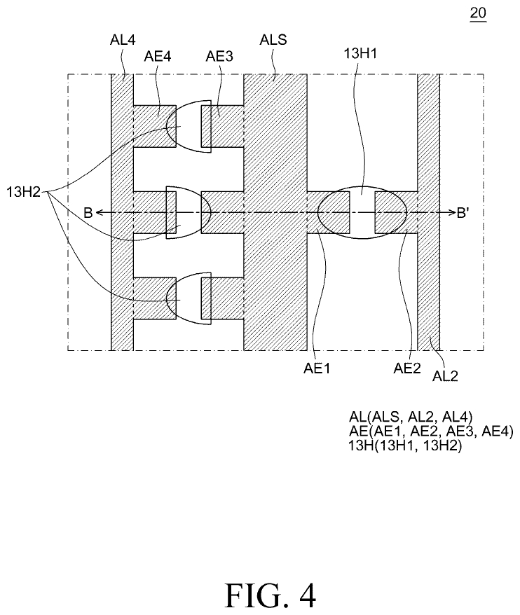

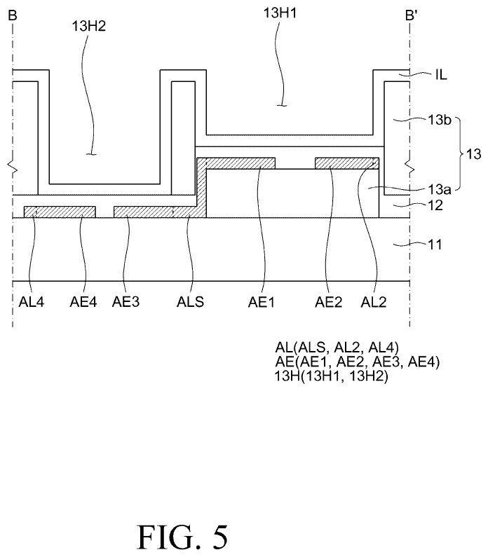

FIG. 4 is an enlarged plan view of an assembly area of an assembly substrate according to another exemplary embodiment of the present disclosure. FIG. 5 is a cross-sectional view taken along B-B′ of FIG. 4. In the assembly substrate 20 of FIGS. 4 and 5, except that the assembly lines AL are different from those of the assembly substrate 10 of FIGS. 1 to 3D, other components are substantially the same, and thus redundant description will be omitted.

Referring to FIGS. 4 and 5, a first assembly line connected to the first assembly electrode AE1 and a third assembly line connected to the third assembly electrode AE3 may be formed integrally. That is, the first assembly electrode AE1 and the third assembly electrode AE3 may share an assembly line. Accordingly, the first assembly electrode AE1 and the third assembly electrode AE3 may be connected through a shared assembly line ALS. Therefore, the same voltage may be applied to the first assembly electrode AE1 and the third assembly electrode AE3 through the shared assembly line ALS.

For example, a voltage different from that applied to the shared assembly line ALS may be simultaneously applied to the second assembly line AL2 and the fourth assembly line AL4. In this case, electric fields may be simultaneously formed between the first assembly electrode AE1 and the second assembly electrode AE2, and between the third assembly electrode AE3 and the fourth assembly electrode AE4, respectively. Accordingly, while the light emitting diode LED is assembled in the first opening 13H1, the defective light emitting diode LED′ may be assembled in the second opening 13H2 at the same time.

However, the present disclosure is not limited thereto, and a voltage different from that applied to the shared assembly line ALS may first be applied to the fourth assembly line AL4 to form an electric field between the third assembly electrode AE3 and the fourth assembly electrode AE4. Accordingly, the defective light emitting diode LED′ may first be assembled in the second opening 13H2. Subsequently, different voltages may be applied to the shared assembly line ALS and the second assembly line AL2 to form an electric field between the first assembly electrode AE1 and the second assembly electrode AE2. Accordingly, the normal light emitting diode LED may be assembled in the first opening 13H1.

The assembly substrate 20 according to another exemplary embodiment of the present disclosure may include the first opening 13H1 and the second opening 13H2 having different sizes. For example, the maximum width of the first opening 13H1 may be formed greater than the maximum width of the light emitting diode LED so as to accommodate the light emitting diode LED. On the other hand, the maximum width of the second opening 13H2 may be formed smaller than the maximum width of the light emitting diode LED. Therefore, the second opening 13H2 may not allow a normal light emitting diode LED to be assembled, but only a defective light emitting diode LED′ in which a part of the normal light emitting diode LED is broken may be assembled. An electric field may be formed in the assembly electrodes AE and the assembly lines AL overlapping the second opening 13H2 to assemble the defective light emitting diode LED′ in the second opening 13H2. That is, the second opening 13H2 may serve to filter the defective light emitting diode LED′. In this way, when the defective light emitting diode LED′ is assembled in the second opening 13H2, the amount of the remaining defective light emitting diodes LED′ may be reduced, thereby improving the assembly rate of the normal light emitting diode LED in the first opening 13H1.

For example, in the assembly substrate 20 according to another exemplary embodiment of the present disclosure, the first assembly electrode AE1 overlapping the first opening 13H1 and the third assembly electrode AE3 overlapping the second opening 13H2 may be connected to each other through the shared assembly line ALS. Accordingly, the same voltage may be applied to the first assembly electrode AE1 and the third assembly electrode AE3 through the shared assembly line ALS. For example, a voltage different from that applied to the shared assembly line ALS may be simultaneously applied to the second assembly line AL2 and the fourth assembly line AL4. Accordingly, an electric field may be simultaneously formed between the first assembly electrode AE1 and the second assembly electrode AE2, and between the third assembly electrode AE3 and the fourth assembly electrode AE4, respectively. Therefore, while the light emitting diode LED is assembled in the first opening 13H1, the defective light emitting diode LED′ may be assembled in the second opening 13H2. That is, in the assembly substrate 20 according to another exemplary embodiment of the present disclosure, the assembly of the normal light emitting diode LED and the filtering of the defective light emitting diode LED′ may be performed simultaneously, thereby simplifying the assembly process.

Meanwhile, in the assembly substrate 20 according to another exemplary embodiment of the present disclosure, the second opening 13H2 in which the defective light emitting diode LED′ is assembled is formed deeper than the first opening 13H1, and the depth of the second opening 13H2 is greater than the height of the defective light emitting diode LED′, so that even when the light emitting diode LED is transferred to the donor DN, the defective light emitting diode LED′ may not contact the donor DN. Accordingly, a defect in which the defective light emitting diode LED′ is transferred onto a display panel through the donor DN may be minimized. That is, in the assembly substrate 20 according to another exemplary embodiment of the present disclosure, the transfer rate of the normal light emitting diode LED may be improved, thereby improving production efficiency.

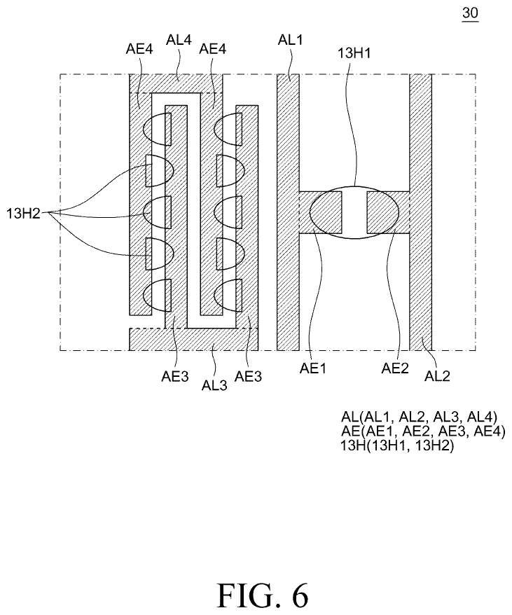

Hereinafter, FIGS. 6 to 8 will be referred to in order to describe various shapes of the assembly lines AL and the assembly electrodes AE.

FIG. 6 is an enlarged plan view of an assembly area of an assembly substrate according to still another exemplary embodiment of the present disclosure. The assembly substrate 30 of FIG. 6, except that only the third assembly electrode AE3, the fourth assembly electrode AE4, the third assembly line AL3, and the fourth assembly line AL4 are different from those of the assembly substrate 10 of FIGS. 1 to 3D, has other components that are substantially the same, and thus redundant description will be omitted.

Referring to FIG. 6, the third assembly line AL3 and the fourth assembly line AL4 may be disposed to face each other. In this case, the third assembly electrode AE3 may extend from the third assembly line AL3 toward the fourth assembly line AL4. Likewise, the fourth assembly electrode AE4 may extend from the fourth assembly line AL4 toward the third assembly line AL3. For example, the third assembly electrode AE3 may be alternately disposed with the fourth assembly electrode AE4 on a plane, but is not limited thereto.

The assembly substrate 30 according to still another exemplary embodiment of the present disclosure may include the first opening 13H1 and the second opening 13H2 having different sizes. For example, the maximum width of the first opening 13H1 may be formed greater than the maximum width of the light emitting diode LED so as to accommodate the light emitting diode LED. On the other hand, the maximum width of the second opening 13H2 may be formed smaller than the maximum width of the light emitting diode LED. Therefore, the second opening 13H2 may not allow a normal light emitting diode LED to be assembled, but only a defective light emitting diode LED′ in which a part of the normal light emitting diode LED is broken may be assembled. Accordingly, an electric field may be formed in the assembly electrodes AE and the assembly lines AL overlapping the second opening 13H2 to assemble the defective light emitting diode LED′ in the second opening 13H2. That is, the second opening 13H2 may serve to filter the defective light emitting diode LED′. In this way, when the defective light emitting diode LED′ is assembled in the second opening 13H2, the amount of the remaining defective light emitting diodes LED′ may be reduced, thereby improving the assembly rate of the normal light emitting diode LED in the first opening 13H1.

In particular, in the assembly substrate 30 according to still another exemplary embodiment of the present disclosure, the second opening 13H2 in which the defective light emitting diode LED′ is assembled is formed deeper than the first opening 13H1, so that even when the light emitting diode LED is transferred to the donor DN, the defective light emitting diode LED′ may not contact the donor DN. Accordingly, a defect in which the defective light emitting diode LED′ is transferred onto a display panel through the donor DN may be minimized. That is, in the assembly substrate 30 according to still another exemplary embodiment of the present disclosure, the transfer rate of the normal light emitting diode LED may be improved, thereby improving production efficiency.

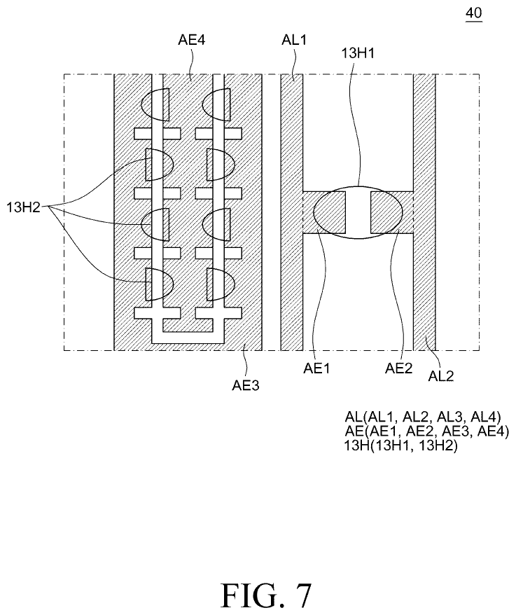

FIG. 7 is an enlarged plan view of an assembly area of an assembly substrate according to still another exemplary embodiment of the present disclosure. The assembly substrate 40 of FIG. 7, except that only the third assembly electrode AE3 and the fourth assembly electrode AE4 are different from those of the assembly substrate 10 of FIGS. 1 to 3D, has other components that are substantially the same, and thus redundant description will be omitted.

Referring to FIG. 7, the third assembly electrode AE3 may be disposed in a “C” shape or a “U” shape on a plane. In this case, the fourth assembly electrode AE4 may be disposed between the third assembly electrodes AE3. For example, the fourth assembly electrode AE4 may be disposed between portions of the third assembly electrodes AE3 facing each other. Accordingly, the third assembly electrode AE3 and the fourth assembly electrode AE4 may be alternately disposed.

The assembly substrate 40 according to still another exemplary embodiment of the present disclosure may include the first opening 13H1 and the second opening 13H2 having different sizes. For example, the maximum width of the first opening 13H1 may be formed greater than the maximum width of the light emitting diode LED so as to accommodate the light emitting diode LED. On the other hand, the maximum width of the second opening 13H2 may be formed smaller than the maximum width of the light emitting diode LED. Therefore, the second opening 13H2 may not allow a normal light emitting diode LED to be assembled, but only a defective light emitting diode LED′ in which a part of the normal light emitting diode LED is broken may be assembled. Accordingly, an electric field may be formed in the assembly electrodes AE and the assembly lines AL overlapping the second opening 13H2 to assemble the defective light emitting diode LED′ in the second opening 13H2. That is, the second opening 13H2 may serve to filter the defective light emitting diode LED′. In this way, when the defective light emitting diode LED′ is assembled in the second opening 13H2, the amount of the remaining defective light emitting diodes LED′ may be reduced, thereby improving the assembly rate of the normal light emitting diode LED in the first opening 13H1.

In particular, in the assembly substrate 40 according to still another exemplary embodiment of the present disclosure, the second opening 13H2 in which the defective light emitting diode LED′ is assembled is formed deeper than the first opening 13H1, so that even when the light emitting diode LED is transferred to the donor DN, the defective light emitting diode LED′ may not contact the donor DN. Accordingly, a defect in which the defective light emitting diode LED′ is transferred onto a display panel through the donor DN may be minimized. That is, in the assembly substrate 40 according to still another exemplary embodiment of the present disclosure, the transfer rate of the normal light emitting diode LED may be improved, thereby improving production efficiency.

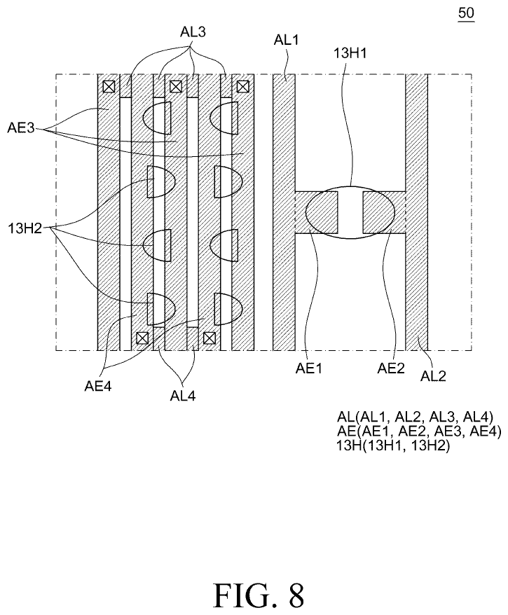

FIG. 8 is an enlarged plan view of an assembly area of an assembly substrate according to still another exemplary embodiment of the present disclosure. The assembly substrate 50 of FIG. 8, except that only the third assembly electrode AE3, the fourth assembly electrode AE4, the third assembly line AL3, and the fourth assembly line AL4 are different from those of the assembly substrate 10 of FIGS. 1 to 3D, has other components that are substantially the same, and thus redundant description will be omitted.

Referring to FIG. 8, the third assembly electrode AE3 and the fourth assembly electrode AE4 may be disposed in a different layer from the third assembly line AL3 and the fourth assembly line AL4. For example, although not illustrated in the drawings, the third assembly electrode AE3 and the fourth assembly electrode AE4 may be respectively disposed on the third assembly line AL3 and the fourth assembly line AL4 with an insulating layer interposed therebetween. Accordingly, the third assembly electrode AE3 may be connected to the third assembly line AL3 through a contact hole of the insulating layer. Likewise, the fourth assembly electrode AE4 may be connected to the fourth assembly line AL4 through a contact hole of the insulating layer, but is not limited thereto.

For example, the third assembly electrode AE3 and the fourth assembly electrode AE4 may be alternately disposed on a plane. For example, the third assembly electrode AE3 and the fourth assembly electrode AE4 may be disposed to extend in a direction perpendicular to the extending direction of the third assembly line AL3 and the fourth assembly line AL4, but is not limited thereto.

The assembly substrate 50 according to still another exemplary embodiment of the present disclosure may include the first opening 13H1 and the second opening 13H2 having different sizes. For example, the maximum width of the first opening 13H1 may be formed greater than the maximum width of the light emitting diode LED so as to accommodate the light emitting diode LED. On the other hand, the maximum width of the second opening 13H2 may be formed smaller than the maximum width of the light emitting diode LED. Therefore, the second opening 13H2 may not allow a normal light emitting diode LED to be assembled, but only a defective light emitting diode LED′ in which a part of the normal light emitting diode LED is broken may be assembled. Accordingly, an electric field may be formed in the assembly electrodes AE and the assembly lines AL overlapping the second opening 13H2 to assemble the defective light emitting diode LED′ in the second opening 13H2. That is, the second opening 13H2 may serve to filter the defective light emitting diode LED′. In this way, when the defective light emitting diode LED′ is assembled in the second opening 13H2, the amount of the remaining defective light emitting diodes LED′ may be reduced, thereby improving the assembly rate of the normal light emitting diode LED in the first opening 13H1.

In particular, in the assembly substrate 50 according to still another exemplary embodiment of the present disclosure, the second opening 13H2 in which the defective light emitting diode LED′ is assembled is formed deeper than the first opening 13H1, so that even when the light emitting diode LED is transferred to the donor DN, the defective light emitting diode LED′ may not contact the donor DN. Accordingly, a defect in which the defective light emitting diode LED′ is transferred onto a display panel through the donor DN may be minimized. That is, in the assembly substrate 50 according to still another exemplary embodiment of the present disclosure, the transfer rate of the normal light emitting diode LED may be improved, thereby improving production efficiency.

The exemplary embodiments of the present disclosure can also be described as follows:

According to an aspect of the present disclosure, there is provided an assembly substrate. The assembly substrate includes an assembly base substrate, a plurality of first assembly electrodes disposed on the assembly base substrate, a plurality of second assembly electrodes disposed on the assembly base substrate so as to face the plurality of first assembly electrodes, a plurality of third assembly electrodes disposed on the assembly base substrate, a plurality of fourth assembly electrodes disposed on the assembly base substrate so as to face the plurality of third assembly electrodes and a first organic layer including a plurality of first openings overlapping the plurality of first assembly electrodes and the plurality of second assembly electrodes, and a plurality of second openings overlapping the plurality of third assembly electrodes and the plurality of fourth assembly electrodes, the plurality of second openings having a smaller size than the plurality of first openings.

In a plan view, an area of the plurality of first openings may be greater than an area of the plurality of second openings.

A depth of the plurality of second openings may be deeper than a depth of the plurality of first openings.

The depth of the plurality of first openings may be less than a height of the plurality of light emitting diodes within the plurality of first openings.

The depth of the plurality of second openings may be greater than a height of the plurality of light emitting diodes within the plurality of second openings.

The plurality of first assembly electrodes and the plurality of second assembly electrodes may be positioned higher than the plurality of third assembly electrodes and the plurality of fourth assembly electrodes on the assembly base substrate.

The assembly substrate may further include a second organic layer disposed between the assembly base substrate and the plurality of first assembly electrodes and the plurality of second assembly electrodes. The second organic layer may be disposed so as not to overlap the plurality of second openings.

The assembly substrate may further include a first assembly line connected to the plurality of first assembly electrodes, a second assembly line connected to the plurality of second assembly electrodes, a third assembly line connected to the plurality of third assembly electrodes and a fourth assembly line connected to the plurality of fourth assembly electrodes. The first assembly line and the third assembly line may be configured such that the same voltage is applied. The second assembly line and the fourth assembly line may be configured such that the same voltage is applied.

The first assembly line and the third assembly line may be formed integrally.

The third assembly line and the fourth assembly line may be disposed to face each other. The plurality of third assembly electrodes may extend from the third assembly line toward the fourth assembly line. The plurality of fourth assembly electrodes may extend from the fourth assembly line toward the third assembly line. The plurality of third assembly electrodes and the plurality of fourth assembly electrodes may be alternately disposed in a plan view.

The assembly substrate may further include an insulating layer disposed on the third assembly line and the fourth assembly line. The plurality of third assembly electrodes may be disposed on the insulating layer and connected to the third assembly line through a contact hole of the insulating layer. The plurality of fourth assembly electrodes may be disposed on the insulating layer and connected to the fourth assembly line through the contact hole of the insulating layer.

The plurality of third assembly electrodes and the plurality of fourth assembly electrodes may be alternately disposed in a plan view.

The plurality of third assembly electrodes may be disposed in a “C” shape or a “U” shape in a plan view. The plurality of fourth assembly electrodes may be disposed between portions of the plurality of third assembly electrodes facing each other.

A planar shape of the plurality of second openings may be a part of a planar shape of the plurality of first openings.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed

description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An assembly substrate for assembling a plurality of light emitting diodes, comprising:
an assembly base substrate;
a plurality of first assembly electrodes disposed on the assembly base substrate;
a plurality of second assembly electrodes disposed on the assembly base substrate so as to face the plurality of first assembly electrodes;
a plurality of third assembly electrodes disposed on the assembly base substrate;
a plurality of fourth assembly electrodes disposed on the assembly base substrate so as to face the plurality of third assembly electrodes; and
a first organic layer including a plurality of first openings overlapping the plurality of first assembly electrodes and the plurality of second assembly electrodes, and a plurality of second openings overlapping the plurality of third assembly electrodes and the plurality of fourth assembly electrodes, the plurality of second openings having a smaller size than the plurality of first openings.

2. The assembly substrate according to claim 1, wherein, in a plan view, an area of the plurality of first openings is greater than an area of the plurality of second openings.

3. The assembly substrate according to claim 1, wherein a depth of the plurality of second openings is greater than a depth of the plurality of first openings.

4. The assembly substrate according to claim 3, wherein the depth of the plurality of first openings is less than a height of the plurality of light emitting diodes within the plurality of first openings.

5. The assembly substrate according to claim 3, wherein the depth of the plurality of second openings is greater than a height of the plurality of light emitting diodes within the plurality of second openings.

6. The assembly substrate according to claim 3, wherein the plurality of first assembly electrodes and the plurality of second assembly electrodes are positioned higher than the plurality of third assembly electrodes and the plurality of fourth assembly electrodes on the assembly base substrate.

7. The assembly substrate according to claim 6, further comprising:
a second organic layer disposed between the assembly base substrate and the plurality of first assembly electrodes and the plurality of second assembly electrodes,
wherein the second organic layer does not overlap the plurality of second openings.

8. The assembly substrate according to claim 1, further comprising:
a first assembly line connected to the plurality of first assembly electrodes;
a second assembly line connected to the plurality of second assembly electrodes;
a third assembly line connected to the plurality of third assembly electrodes; and
a fourth assembly line connected to the plurality of fourth assembly electrodes,
wherein the first assembly line and the third assembly line are configured such that the same voltage is applied, and
the second assembly line and the fourth assembly line are configured such that the same voltage is applied.

9. The assembly substrate according to claim 8, wherein the first assembly line and the third assembly line are integral as a common assembly line.

10. The assembly substrate according to claim 8, wherein the third assembly line and the fourth assembly line are disposed to face each other,
the plurality of third assembly electrodes extends from the third assembly line toward the fourth assembly line,
the plurality of fourth assembly electrodes extends from the fourth assembly line toward the third assembly line, and
the plurality of third assembly electrodes and the plurality of fourth assembly electrodes are alternately disposed in a plan view.

11. The assembly substrate according to claim 8, further comprising:
an insulating layer disposed on the third assembly line and the fourth assembly line,
wherein the plurality of third assembly electrodes is disposed on the insulating layer and connected to the third assembly line through a contact hole of the insulating layer, and
the plurality of fourth assembly electrodes is disposed on the insulating layer and connected to the fourth assembly line through the contact hole of the insulating layer. 12, The assembly substrate according to claim 11, wherein the plurality of third assembly electrodes and the plurality of fourth assembly electrodes are alternately disposed in a plan view.

13. The assembly substrate according to claim 1, wherein the plurality of third assembly electrodes is disposed in a “C” shape or a “U” shape in a plan view, and
the plurality of fourth assembly electrodes is disposed between portions of the plurality of third assembly electrodes facing each other.

14. The assembly substrate according to claim 1, wherein a planar shape of the plurality of second openings is a part of a planar shape of the plurality of first openings.
